(19) United States
(12) Patent Application Publication
(10) Pub. No.: US 2025/0390027 A1
(43) Pub. Date: Dec. 25, 2025

(54) LITHOGRAPHIC APPARATUS AND METHOD FOR OPERATING THE SAME

(71) Applicant: TAIWAN SEMICONDUCTOR MANUFACTURING COMPANY, LTD., Hsinchu (TW)

(72) Inventors: Shih-Yu TU, Hsinchu County (TW); Wei-Huai CHIU, Miaoli County (TW); Chieh HSIEH, Taoyuan City (TW); Sheng-Kang YU, Hsinchu City (TW); Han-Lung CHANG, Kaohsiung City (TW); Li-Jui CHEN, Hsinchu City (TW)

(73) Assignee: TAIWAN SEMICONDUCTOR MANUFACTURING COMPANY, LTD., Hsinchu (TW)

(21) Appl. No.: 18/748,292

(22) Filed: Jun. 20, 2024

(51) Int. Cl. G03F 7/00; G01M 11/02; H05G 2/00

(52) U.S. Cl. CPC G03F 7/70591; G01M 11/0278; G03F 7/70033; G03F 7/702; G03F 7/70233; G03F 7/7085; G03F 7/70925; G03F 7/70975; H05G 2/0084; H05G 2/0086

(57) ABSTRACT

A method for operating a lithography apparatus is provided. The method includes using a laser generator, emitting a laser beam; using a radiation source, producing extreme ultraviolet radiation by hitting the target droplet by the laser beam; using a scanner, directing the EUV radiation onto a substrate through a mask; and performing an in-line inspection process on a target component in one of the laser generator, the radiation source, and the scanner when producing the EUV radiation.

### BACKGROUND

Photolithography is a process by which a reticle having a pattern is irradiated with light to transfer the pattern onto a photosensitive material overlying a semiconductor substrate. Over the history of the semiconductor industry, smaller integrated chip minimum features sizes have been achieved by reducing the exposure wavelength of optical lithography radiation sources to improve photolithography resolution. Extreme ultraviolet (EUV) lithography, which uses extreme ultraviolet (EUV) light, is a promising next-generation lithography solution for emerging technology nodes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography apparatus according to some embodiments of the present disclosure.

FIG. 2 is schematic view of an inspection device inspecting a target component in a lithography apparatus according to some embodiments of the present disclosure.

FIG. 3 is schematic view of an inspection device inspecting a target component in a lithography apparatus according to some embodiments of the present disclosure.

FIG. 4 is schematic view showing an inspection device inspecting a target component in a scanner in a lithography apparatus according to some embodiments of the present disclosure.

FIG. 5 is schematic view showing an inspection device inspecting a target component in a radiation source in a lithography apparatus according to some embodiments of the present disclosure.

FIG. 6 is schematic view showing an inspection device inspecting a target component in a laser generator providing a laser to a radiation source in a lithography apparatus according to some embodiments of the present disclosure.

FIG. 7 is schematic view of an inspection device inspecting a target component in a lithography apparatus according to some embodiments of the present disclosure.

FIGS. 8A-8F are respectively cross-sectional views of fiber structures in accordance with various embodiments.

FIG. 9 is schematic view of an inspection device inspecting a target component in a lithography apparatus according to some embodiments of the present disclosure.

FIG. 10 is schematic view of an inspection device inspecting a target component in a lithography apparatus according to some embodiments of the present disclosure.

FIG. 11 is schematic view of an inspection device inspecting a target component in a lithography apparatus according to some embodiments of the present disclosure.

FIG. 12 is schematic view of an inspection device inspecting a target component in a lithography apparatus according to some embodiments of the present disclosure.

FIG. 13 is schematic view of an inspection device inspecting plural target components in a lithography apparatus according to some embodiments of the present disclosure.

FIG. 14 is a flow chart of a method for operating a lithography apparatus according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An extreme ultraviolet (EUV) photolithography system uses extreme ultraviolet radiation. One method of producing the extreme ultraviolet radiation is to emit a laser to droplets of tin. As the tin droplets are produced into the EUV radiation source vessel, the laser hits the tin droplets and heats the tin droplets to a temperature that causes atoms of tin to shed their electrons and become a plasma of ionized tin droplets. The ionized tin droplets emit photons, which is collected by a collector and provided as EUV radiation to an optical lithography system.

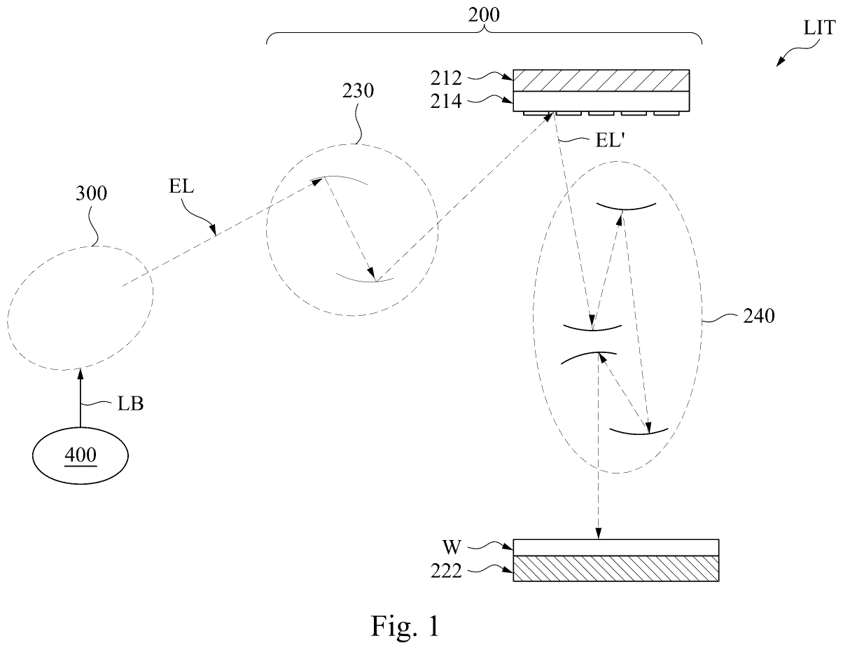

FIG. 1 is a schematic view of a lithography apparatus LIT according to some embodiments of the present disclosure. The lithography apparatus LIT may include a scanner 200 that is operable to perform lithography exposing processes, a radiation source 300, and a laser generator 400. In some embodiments, the scanner 200 is an extreme ultraviolet (EUV) lithography system designed to expose a resist layer on a semiconductor substrate W by EUV light (or EUV radiation). The resist layer is a material sensitive to the EUV light. The radiation source 300 is used to generate EUV light EL to the scanner 200. In some embodiments, EUV light has a wavelength ranging between about 1 nm and about 100 nm. In certain examples, the EUV light EL has a wavelength range centered at about 13.5 nm. Accordingly, the radiation source 300 is also referred to as an EUV radiation source 300. The EUV radiation source 300 may utilize a mechanism of laser-produced plasma (LPP) to generate the EUV radiation. The laser generator 400 is used to provide a laser beam LB to the radiation source 300 for EUV excitation. In the present embodiments, the semiconductor substrate W is a semiconductor wafer, such as a silicon wafer or other type of wafer to be patterned. The semiconductor substrate W is coated with a resist layer sensitive to the EUV light in the present embodiments.

The scanner 200 may include a mask stage 212 configured to secure a mask 214. In some embodiments, the mask stage 212 includes an electrostatic chuck (e-chuck) used to secure the mask 214. In this context, the terms mask, photomask, and reticle are used interchangeably. In the present embodiments, the mask 214 is a reflective mask. One exemplary structure of the mask 214 includes a substrate with a low thermal expansion material (LTEM). For example, the LTEM may include TiO₂ doped SiO2, or other suitable materials with low thermal expansion. The mask 214 includes a reflective multi-layer deposited on the substrate. The reflective multi-layer includes plural film pairs, such as molybdenum-silicon (Mo/Si) film pairs (e.g., a layer of molybdenum above or below a layer of silicon in each film pair). Alternatively, the reflective multi-layer may include molybdenum-beryllium (Mo/Be) film pairs, or other suitable materials that are configurable to highly reflect the EUV light EL. The mask 214 may further include a capping layer, such as ruthenium (Ru), disposed on the reflective multi-layer for protection. The mask 214 further includes an absorption layer, such as a tantalum boron nitride (TaBN) layer, deposited over the reflective multi-layer. The absorption layer may be patterned to define a layer of an integrated circuit (IC). The EUV light EL carrying a pattern of the mask 214 may be referred to as EUV light EL'. The mask 214 may have other structures or configurations in various embodiments.

In some embodiments, the scanner 200 may include an illuminator optical module 230. The illuminator optical module 230 includes various reflective optics such as a single mirror or a mirror system having multiple mirrors in order to direct the EUV light EL from the radiation source 300 onto a mask stage 214, particularly to a mask 214 secured on the mask stage 212.

The scanner 200 may also include a projection optical module (or projection optics box (POB)) 240 for imaging the pattern of the mask 214 onto a semiconductor substrate W secured on the substrate stage (or wafer stage) 222 of the scanner 200. The projection optical module 240 includes reflective optics in the present embodiments. The light EL' that is directed from the mask 214 and carries the image of the pattern defined on the mask 214 is collected by the projection optical module 240. Various components including those described above are integrated together and are operable to perform lithography exposing processes.

In some embodiments, the radiation source 300 may generate EUV light EL by producing a high-temperature plasma, which may cool down and become vapors or small particles (collectively, debris). The debris may deposit onto various components/surfaces of the lithography apparatus LIT, thereby causing contamination thereon. Also, some other particles, such as metal elements (e.g., aluminum, iron, aluminum oxide) or non-metal elements (e.g., boron, nitride), which may come/outgas from some axillary components in the scanner 200 in the lithography apparatus LIT, may also cause contamination various components/surfaces of the lithography apparatus LIT. The contamination may degrade performance of the components/surfaces of the lithography apparatus LIT. For example, the reflectivity of the reflective mirrors in the radiation source 300 (e.g., the collector) and/or the reflective mirrors in the scanner 200 may degrade due to contamination thereon. Also, some other particles, such as aluminum oxide, may also cause, and once the reflectivity is degraded to a certain degree, the reflective mirrors reach the end of its usable lifetime and may be swapped out.

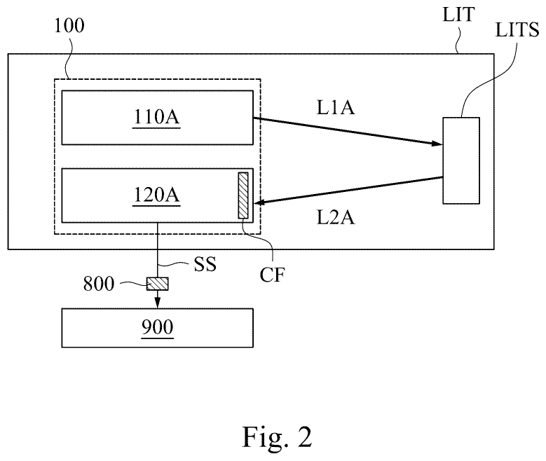

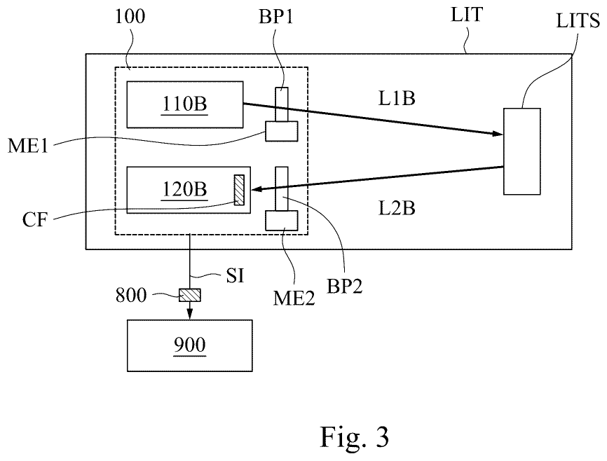

In some embodiments of the present embodiments, an inspection device 100 (referring to FIGS. 2 and 3) can be used to inspect/check a particle condition on the components/surfaces of the lithography apparatus LIT exposed to particle contamination for checking the availability of the components/surfaces of the lithography apparatus LIT. The components/surfaces of the lithography apparatus LIT to be inspected may be later referred to as a target component LITS in the lithography apparatus LIT in FIGS. 2 and 3. The target component LITS can be any point/position/surface in the lithography apparatus LIT potentially being contaminated by particles.

FIG. 2 is schematic view of an inspection device 100 inspecting a target component LITS in the lithography apparatus LIT according to some embodiments of the present disclosure. The inspection device 100 can be disposed in the lithography apparatus LIT. The inspection device 100 may include a light source 110A and a light detector 120A. The light source 110A may provide a light L1A to the target component LITS, and the light detector 120A may receive the light L2A provided/emitted from the target component LITS. The light L1A provided by the light source 110A may have a suitable wavelength for detecting elements (e.g., silver nanoparticles, copper ions, CO₂, the like, or the combination thereof) on the target component LITS. The light L1A is capable of exciting atoms and ions in the material/particles on the target component LITS. By directing the light L1A onto the surface of the material/particles on the target component LITS, a transient micro-plasma is produced by exciting atoms and ions in the material/particles on the target component LITS, and radiation (e.g., the light L2A) is emitted from excited atoms and ions produced within the transient micro-plasma. The light source 110A can be any light source (e.g., high-power light source) providing the light L1A capable of exciting atoms and ions in the material/particles on the target component LITS. For example, the light source 110A can be a laser, a laser diode, a light-emitting diode (LED), the like, or the combination thereof. The light source 110A can be a monochromatic light source, a multichromatic light source, or a broadband light source.

The light detector 120A may be a spectrometer capable of detecting a spectrum of a radiation (e.g., the light L2A) from the target component LITS in the lithography apparatus LIT. For example, analytical information/data derives from time and spectrally resolving the radiation (e.g., the light L2A) detected by the light detector 120A forms an emission spectrum as a result of the measurements of the light detector 120A. The detected spectrum of the light detector 120A may cover the UV light (e.g., about 300 nm to about 400 nm) and/or visible light (e.g., about 380 nm to about 780 nm). In some embodiments, the light detector 120A is a complementary metal-oxide-semiconductor (CMOS) sensor equipped with a band (color) filter CF that blocks undesired wavelength range. For example, the color filters CF may be a red filter, a blue filter, or a green filter. In some embodiments, the light detector 120A can be referred to as a light receiver.

A controller 900 is electrically coupled with the light detector 120A for receiving a digital spectrum signal SS carrying information of the emission spectrum and determining a condition of the inspected elements based on the digital spectrum signal SS. Characteristic peaks in the emission spectrum lead to the determination of the elements contained in the minute amount of material ablated, reflecting the local elemental composition of the material/particles on the target component LITS. The peak intensity can, in principle, be associated with the number density of each emitting species with the concentration of specific elements in the ablated material. Thus, the elements (e.g., tin particles, silver nanoparticles, copper ions, CO₂, the like, or the combination thereof) can be determined by the data of the detected radiation (e.g., the light L2A). In some embodiments, the light detector 120A is capable of detecting a wavelength range covering characteristic peak(s) of the element(s) to be detected. For example, for detecting copper ions, the operating wavelength range of the light detector 120A would cover about 808 nanometers. For detecting silver nanoparticles, the operating wavelength range of the light detector 120A would cover about 532 nanometers. For detecting CO₂, the operating wavelength range of the light detector 120A would cover about 2500 nanometers. In some embodiments, the band (color) filter CF is chosen to allow the characteristic peak of the elements (e.g., tin particles, silver nanoparticles, copper ions, CO₂, the like, or the combination thereof) to pass itself, and block light with a certain wavelength far away from the characteristic peak of the elements (e.g., tin particles, silver nanoparticles, copper ions, CO₂, the like, or the combination thereof).

The controller 900 may include a computer-readable storage medium and a processor coupled to the computer-readable storage medium. The computer-readable storage medium stores program that controls various steps performed in the inspection device 100. For example, the controller 900 may control the measurements of light data, analyze the data of the detected radiation (e.g., the light L2A), and send out a massage/signal showing the determined condition of the inspected elements, by using the processor reading out and executing the program stored in the storage medium. The program may be one that has been stored in the computer-readable storage medium, or may be one that has been installed to the storage medium of the controller 900. The controller 900 may be a personal computer or a mobile phone. In some embodiments, a signal convertor 800 may be connected between the controller 900 and the light detector 120A for signal conversion.

In some embodiments, the light L1A provided by the light source 110A may not substantially expose the resist layer over the semiconductor substrate W (referring to FIG. 1). As a result, a peak wavelength of the light L1A provided the light source 110A may be different from a peak wavelength of the EUV light EL provided by the radiation source 300. For example, a peak wavelength of the radiation source 300 may be extreme ultraviolet (EUV) light, while a peak wavelength of the light source 110A may be in visible light spectrum or the deep ultraviolet light (DUV).

FIG. 3 is schematic view of an inspection device 100 inspecting a target component LITS in a lithography apparatus LIT (referring to FIG. 1) according to some embodiments of the present disclosure. Details of the present embodiments are similar to those illustrated in the embodiments of FIG. 2, except that the inspection device 100 include a light detector 120B, which may be an image sensor (e.g., camera, charge-coupled device (CCD)) for capturing images of the target component LITS. For example, the light detector 120B includes a plurality of active-pixel CMOS sensors. In the present embodiments, the band (color) filter CF may be an array of different color filters respectively corresponding to the active-pixel CMOS sensors, such as an array of red filters, blue filters, and green filters. For example, the band (color) filter CF may be a Bayer filter. In some embodiments, the light source 110B may provide a light L1B to the target component LITS, and the light detector 120B receives the light L2B reflected by from the target component LITS, in which the light L2B carries image information of the target component LITS.

In the present embodiments, the inspection device 100 may include a polarizer PB1 and/or a polarizer PB2, in which the polarizer PB1 is optically coupled between the light source 110B and the target component LITS for controlling a polarization state of the light L1B, and the polarizer PB2 is optically coupled between the light detector 120B and the target component LITS for controlling a polarization state of the light L2B. In some embodiments, one of the polarizers PB1 and PB2 can be omitted, and the other polarizers PB1 and PB2 is used for controlling a polarization state of the light L1B/L2B. For example, in some embodiments, the light L1B is unpolarized when the polarizer PB1 is omitted, and the polarizer PB2 is used to a allow different polarization states of the light L2B passing itself at different time durations. In some other embodiments, both the polarizers PB1 and PB2 are used for controlling a polarization state of the light L1B and L2B. The controller 900 may be electrically connected to an electrically-rotatable holder ME1/ME2 supporting the polarizer PB1/PB2 for controlling/tuning/rotating a polarization axis of the polarizer PB1/PB2.

At a first time duration, the polarizer PB1/PB2 is controlled to allow a light of a first polarization state passing itself; and at a second time duration, the polarizer PB1/PB2 is controlled to allow a light of a second polarization state passing itself. The second polarization state may be different from the first polarization state, and the second time duration does not overlap the first time duration. In some examples, a polarization axis of the first polarization state at the first time duration is orthogonal to a polarization axis of the second polarization state at the second time duration, such as P-polarized light and S-polarized light. In some examples, an angle between polarization axis of the first polarization state at the first time duration and the polarization axis of the second polarization state at the second time duration can be in a range from about 0 degrees to about 90 degrees. Through the configuration, the image of the target component LITS can be captured by the light of the first polarization state (e.g., P-polarized light) at the first time duration, and the image of the target component LITS can be captured by the light of the second polarization state (e.g., S-polarized light) at the second time duration. With the images of two different polarization states, and condition of the elements (e.g., silver nanoparticles, copper ions, CO₂, the like, or the combination thereof) on the target component LITS can be well determined. The polarizers PB1 and PB2 are illustrated as linear polarizers in the present embodiments. In some other embodiments, the polarizers PB1 and PB2 are not limited to the linear polarizers. For example, the polarizers PB1 and PB2 can be circular polarizers.

The controller 900 is electrically coupled with the light detector 120B for receiving digital image signals SI carrying image information. The controller 900 may determine a condition/distribution of the particle (e.g., size and shape) and a species of the particle based on the digital image signals SI. Analytical information/data derives from a map of differences of contrast ratios between the images of two different polarization states as a result of the measurements. Thus, the condition/distribution of the particle and a species of the particle can be determined by the data of the images of two different polarization states.

In the present embodiments, the light source 110B can be a monochromatic light source, a multichromatic light source, or a broadband light source. In some embodiments, the light L1B provided by the light source 110B may not substantially expose the resist layer over the semiconductor substrate W (referring to FIG. 1). As a result, a peak wavelength of the light L1B provided the light source 110B may be different from a peak wavelength of the EUV light EL provided by the radiation source 300. For example, a peak wavelength of the radiation source 300 may be extreme ultraviolet (EUV) light, while a peak wavelength of the light source 110A may be in visible light spectrum or the deep ultraviolet light (DUV). Other details of the present embodiments are similar to those illustrated in the embodiments of FIG. 2, and therefore not repeated herein.

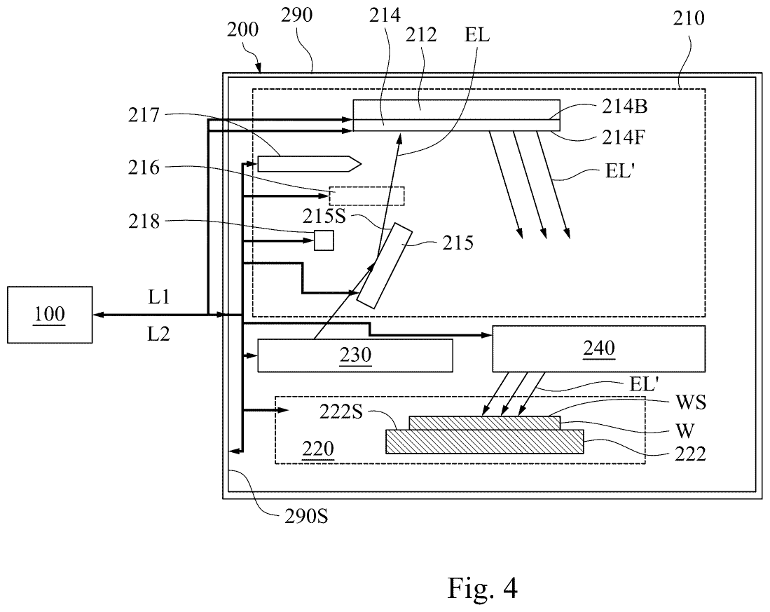

FIG. 4 is schematic view showing an inspection device 100 inspecting a target component in a scanner 200 in a lithography apparatus LIT (referring to FIG. 1) according to some embodiments of the present disclosure. As shown in embodiments of FIG. 2 and FIG. 3, the inspection device 100 provides the light L1 and receives the light L2 for inspection. In the context, the light L1 and L2 may be the light L1A and L2A in the embodiments of FIG. 2 or the light LIB and L2B in the embodiments of FIG. 3. The scanner 200 may include a mask region 210, a substrate stage region 220, the illuminator optical module 230, the projection optical module 240, and a wall 290 surrounding the mask region 210, the substrate stage region 220, the illuminator optical module 230, and the projection optical module 240.

The mask region 210 may include the mask stage 212 configured to secure the mask 214, a plane deflection mirror 215, an optical element 216, a light shielding element 217, and some other optical elements 218. The plane deflection mirror 215 is operated with grazing incidence. The optical element 216 may include plural reflective mirrors configured to adjust a distribution of EUV light EL to be more uniform. The light shielding element 217 includes a light absorptive material, and is configured to block an undesired portion of the EUV light EL from being directed to the mask 214. The other optical elements 218 may be optical elements adjacent to the plane deflection mirror 215 or any other suitable optical elements.

In the present embodiments, the inspection device 100 is used to inspect the various components/surfaces of the scanner 200 in the lithography apparatus LIT. For example, the inspected target component LITS (referring to FIGS. 2 and 3) can be the wall 290, the mask region 210, the substrate stage region 220, the illuminator optical module 230, and the projection optical module 240. In some examples, the inspection device 100 may inspect an inner surface 290S of the wall 290, reflective surfaces of mirrors in the illuminator optical module 230, and reflective surfaces of mirrors the projection optical module 240. In some examples of the mask region 210, the inspected target component LITS can be the mask 214, the plane deflection mirror 215, the optical element 216, the light shielding element 217, and the other optical elements 218. For example, the inspection device 100 may inspect the inner surface 290S of the wall 290, a front surface 214F of the mask 214 facing the substrate stage (or wafer stage) 222, a back surface 214B of the mask 214 facing away from the substrate stage (or wafer stage) 222, a reflective surface 215S of the plane deflection mirror 215, any surface of the optical element 216, any surface of the light shielding element 217, and any surface of the other optical elements 218. In some examples of the substrate stage region 220, the inspected target component LITS can be the substrate stage (or wafer stage) 222 and the semiconductor substrate W. For example, the inspection device 100 may inspect a top surface 222S of the substrate stage (or wafer stage) 222 and a top surface WS of the semiconductor substrate W.

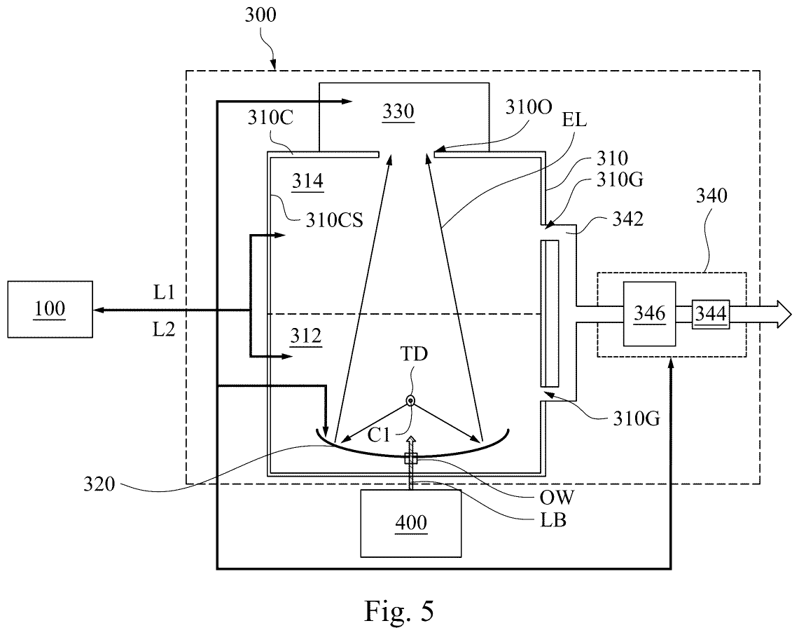

FIG. 5 is schematic view showing an inspection device 100 inspecting a target component in a radiation source 300 in a lithography apparatus LIT (referring to FIG. 1) according to some embodiments of the present disclosure. The radiation source 300 may include a vessel 310, a collector 320, an intermediate focus (IF)-cap module 330, and a gas exhaust system 340. In some embodiments, the vessel 310 has a cover 310C surrounding itself, and the cover 310C is around the collector 320. The collector 320 is configured in an enclosed space in the vessel 310. The space in the vessel 310 is maintained in a vacuum environment since the air absorbs the EUV radiation.

A laser generator 400 may be at a bottom side of the vessel 310 and below the collector 320. The laser generator 400 may include a carbon dioxide (CO2) laser source, a neodymium-doped yttrium aluminum garnet (Nd: YAG) laser source, or another suitable laser source to generate a laser beam LB. The laser beam LB is directed through an output window OW integrated with the collector 320. The output window OW adopts a suitable material substantially transparent to the laser beam LB. The laser beam LB is directed to heating droplets of fuel material TD, such as tin droplets, thereby generating high-temperature plasma (e.g., ionized tin droplets) which further produces the EUV light EL. In some embodiments, the fuel material TD are tin (Sn) droplets. Other materials may also be used for the fuel material TD, for example, a tin-containing liquid material such as eutectic alloy containing tin, lithium (Li), and xenon (Xe). The point where the laser beam LB heats the droplets of fuel material TD can be referred to as a plasma-generated point C1.

The collector 320 may collect the EUV light EL, and reflect and focus the EUV light EL to the scanner 200, through an exit aperture 3100 of the vessel 310. The collector 320 is designed with suitable coating material and shape, functioning as a mirror for EUV collection, reflection, and focus. In some examples, the collector 320 is designed to have an ellipsoidal geometry. In some examples, the coating material of the collector 320 is similar to the reflective multilayer of the mask 214 (referring to FIG. 4). In some examples, the coating material of the collector 320 includes a ML (such as a plurality of Mo/Si film pairs) and may further include a capping layer (such as Ru) coated on the ML to substantially reflect the EUV light. In some examples, the collector 320 may further include a grating structure designed to effectively scatter the laser beam directed onto the collector 320. For example, a silicon nitride layer may be coated on the collector 320 and patterned to have a grating structure.

The IF-cap module 330 is out of the exit aperture 3100, and the IF-cap module 330 is configured to provide intermediate focus to the EUV radiation EL from the exit aperture 310O to the scanner 200. The vessel 310 may be composed of a lower vessel 312 near the plasma-generated point C1 and an upper vessel 314 far away from the plasma-generated point C1.

In some embodiments, the gas exhaust system 340 may be referred to as an inline debris remover system with exhaust lines 342, a pump 344, and a debris handling device 346. The exhaust lines 342 may be connected to gas outlets 310G of the vessel 310 at the wall of the vessel 310 for receiving the exhaust. To further these embodiments, the exhaust line 342 is connected to the cover 310C. The pump 314 draws airflow from the vessel 310 into the exhaust lines 312 for effectively pumping out the gas. The gas may also function to carry some debris away from the collector 320 and the cover 310C and into the gas exhaust system 340. The debris handling device 346 may be coupled with the exhaust lines 342, between the vessel 310 and the pump 344, for removing (e.g., scrubbing/filtering) debris from the gas. In some embodiments, the debris handling device 346 may be a scrubber, which may passively scrub some debris from the gas.

In the present embodiments, the inspection device 100 is used to inspect the various components/surfaces of the radiation source 300 in the lithography apparatus LIT. For example, the inspected target component LITS (referring to FIGS. 2 and 3) can be the cover 310C, the lower vessel 312, the upper vessel 314, the collector 320, the IF-cap module 330, and the gas exhaust system 340. For example, the inspection device 100 may inspect the inner surface 310CS of the cover 310C, any surface of the lower vessel 312, any surface of the upper vessel 314, a reflective surface of the collector 320, any surface of the IF-cap module 330, and any surface of the gas exhaust system 340.

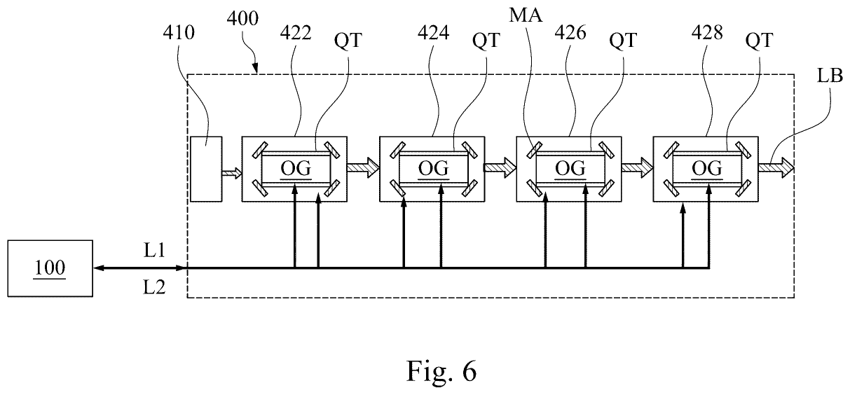

FIG. 6 is schematic view showing an inspection device 100 inspecting a target component in a laser generator 400 providing a laser LB to a radiation source 300 in a lithography apparatus LIT (referring to FIG. 1) according to some embodiments of the present disclosure. The laser generator 400 may include a main pulse seed laser source 410 and amplifier chambers 422-428. The amplifier chambers 422-428 may be respectively provided with optical gain materials OG positioned along a beam path BP. In some embodiments, the laser generator 400 may further include cooling systems used to cool the optical gain materials OG in the amplifier chambers 422-428 for operating the laser generator 400 at higher powers.

In some embodiments, the main pulse seed laser 410 may be a CO₂ laser having a sealed gas including CO₂ at sub-atmospheric pressure, which is pumped by a radio-frequency discharge. Where this is the case, the optical gain materials OG provided in the amplifier chambers 422-428 may be CO₂ gas. Other gases may also be provided within the amplifier chambers 422-428. The optical gain materials OG may be contained in quartz tubes QT, respectively. In some embodiments, the amplifier chambers 422-428 are set up with mirrors MA to reflect the laser beam LB which leaves the optical gain materials OG back into the optical gain materials OG, thereby increasing the power of the laser beam LB. The mirrors MA may for example be a flat mirror, curved mirror, phase-conjugate mirror or corner reflector.

In the present embodiments, the inspection device 100 is used to inspect the various components/surfaces of the laser generator 400 of the lithography apparatus LIT. The inspected target component LITS (referring to FIGS. 2 and 3) can be the mirrors MA, the amplifier chambers 422-428, and the quartz tubes QT. For example, the inspection device 100 may inspect the reflective surface of the mirrors MA, inner surfaces of the amplifier chambers 422-428, the outer surface of the quartz tubes QT, or the inner surface of the quartz tubes QT.

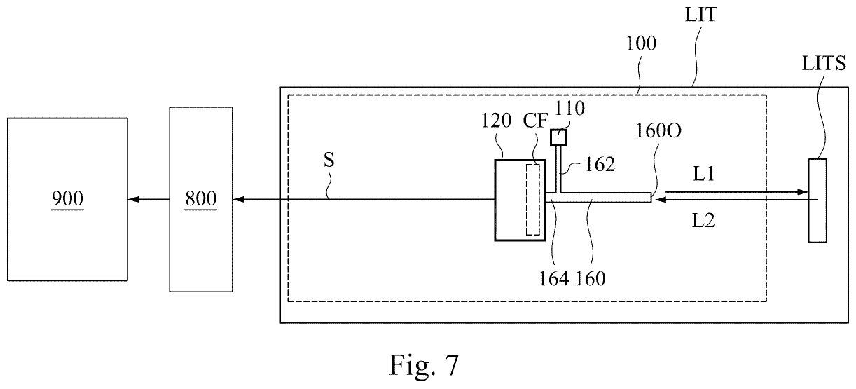

FIG. 7 is schematic view of an inspection device 100 inspecting a target component LITS in a lithography apparatus according to some embodiments of the present disclosure. The inspection device 100 may include a light source 110, a light detector 120, and a fiber structure 160. The light source 110 may indicate the light source 110A in FIG. 2 and/or the light source 110B in FIG. 3. The light detector 120 may indicate the light detector 120A in FIG. 2 and/or the light detector 120B in FIG. 3.

The fiber structure 160 may a coaxial fiber including first and second fibers 162 and 164. The first and second fibers 162 and 164 have first ends respectively optically coupled with the light source 110 and the light detector 120, and second ends (e.g., collectively referred to as an end 160O of the fiber structure 160) facing the target component LITS. With the configuration, the first fiber 162 guides the light L1 from the light source 110 to the target component LITS, and the second fibers 164 guide the light L2 from the target component LITS to the light detector 120. As aforementioned, in the embodiments illustrated in FIG. 2, the light L1 may excite atoms and ions in the material/particles on the target component LITS, and the light L2 may be an emission spectrum including characteristic peaks revealing the elements in the material/particles on the target component LITS. In the embodiments illustrated in FIG. 3, the light L1 may be polarized light, and the light L2 may carry image information of the target component LITS illuminated by the polarized light. In some embodiments, each of the second fibers 164 carries image information of the target component LITS. In some alternative embodiments, each of the second fibers 164 carries information of one of pixels of the image of the target component LITS, and the information of plural pixels in combination serve as the image information. As a result, the inspection device 100 may send signals S (e.g., the digital spectrum signal SS in FIG. 2 or the digital image signals SI in FIG. 3) to the signal convertor 800 and the controller 900.

The end 160O of the fiber structure 160 may be spaced apart from the target component LITS by a distance determined by depth of focus. If the end 1600 of the fiber structure 160 is spaced apart from the target component LITS too far, the light intensity may be too weak to inspect/excite the material/particles on the target component LITS. If the end 160O of the fiber structure 160 is spaced apart from the target component LITS too near, the inspection result may be seriously influenced by background's signal noise ratio (SNR). In some embodiments, the end 160O of the fiber structure 160 may also be referred to as a fiber, a fiber probe, or a probe end. In some embodiments, a position of the end 160O of the fiber structure 160 is moved for adjusting an incident angle of the light L1 (referring to FIG. 7). In some embodiments, a cross-sectional area of the first fiber 162 can be adjusted for adjusting a spot size of the light L1 (referring to FIG. 7).

In some embodiments, the fiber 162 may extend along a direction substantially normal to a surface of the target component LITS. For example, an angle between an extension line of the fiber 162 and a direction normal to the surface of the target component LITS may be in a range from about 80 degrees to about 100 degrees. In some embodiments, the fiber 164 may extend along a direction substantially normal to the surface of the target component LITS. For example, an angle between an extension line of the fiber 164 and a direction normal to the surface of the target component LITS may be in a range from about 80 degrees to about 100 degrees. Through the configuration, paths of the light L1 and L2 are substantially normal to the surface of the target component LITS.

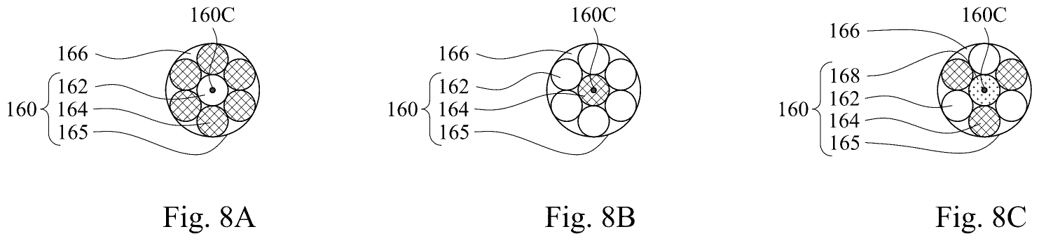

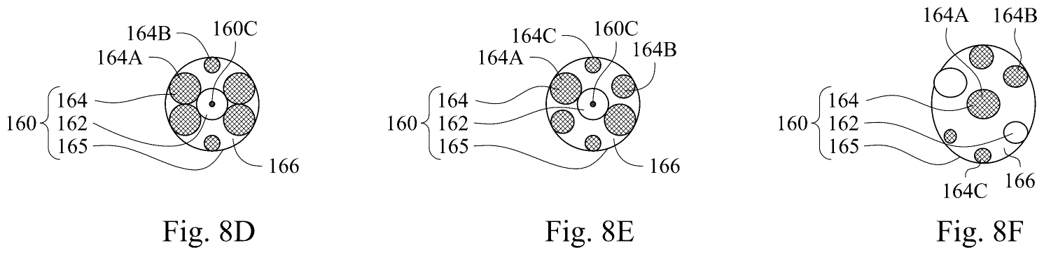

FIGS. 8A-8F are respectively cross-sectional views of fiber structures 160 in accordance with various embodiments. The cross-sections of the fiber structures 160 may affect light intensity and detection resolution. By adjusting the cross-sections of the fiber structures 160, the shape and intensity of light can be altered, and the spot of incidence and reflected light can also be adjusted.

Reference is made to FIG. 8A. In the present embodiments, the first fiber 162 may be located at a center axis 160C of the coaxial fiber structure 160, and the second fibers 164 may be offset from the center axis 160C of the coaxial fiber structure 160, for example, arranged in a ring around the first fiber 162. In the present embodiments, a diameter of the first fiber 162 may be substantially equal to a diameter of the second fibers 164. In some other embodiments, a diameter of the first fiber 162 may be different from a diameter of the second fibers 164. For example, a diameter of the first fiber 162 may be greater than or less than a diameter of the second fibers 164. In some embodiments, the first fiber 162 and the second fibers 164 may be arranged in other configurations.

The fiber structure 160 may have an outer jacket 165, serving as a wall surrounding the first fiber 162 and the second fibers 164. Material of the outer jacket 165 may include polyethylene, polyvinyl chloride, polyvinyl difluoride, the like, or the combination thereof. The fiber structure 160 may also have a filling material 166 filling the space among the first fiber 162, the second fibers 164, and the outer jacket 165. The filing material 166 may include suitable compounds.

In the present embodiments, the fiber structure 160 may be a multi-core structure. For example, the first and second fibers 162 and 164 is made of a light transmissive core material having a relatively high index of refraction and the filling material 166 is made of a cladding material having a relatively lower index of refraction than the light transmissive core material. In some alternative embodiments, the fibers 162 and 164 are constructed of a light transmissive core material having a relatively high index of refraction and surrounded by a cladding material having a relatively lower index of refraction than that of the light transmissive core material. In such embodiments, the filling material 166 may be made of any suitable material, not limit to be having a lower index of refraction than that of the light transmissive core material. In some other embodiments, the first and second fibers 162 and 164 are a graded-index optical fiber in which the index of refraction in the core decreases continuously between the axis of the optical fiber and the boundary of the core with the cladding material.

Reference is made to FIG. 8B. Embodiments of the present embodiments are similar to that of FIG. 8A, except that the configurations of the first fibers 162 and the second fibers 164 are exchanged in the present embodiments. In the present embodiments, the second fiber 164 may be located at a center axis 160C of the coaxial fiber structure 160, and the first fibers 162 may be offset from the center axis 160C of the coaxial fiber structure 160, for example, arranged in a ring around the second fiber 164. In the present embodiments, a diameter of the first fiber 162 may be substantially equal to a diameter of the second fibers 164. In some other embodiments, a diameter of the first fiber 162 may be greater than or less than a diameter of the second fibers 164. In some embodiments, the first fibers 162 may be coupled with a same light source 150. In some alternative embodiments, the first fibers 162 may be coupled with various light sources 150 with different spectrums. For example, a first group of the first fibers 162 are coupled with light with a first wavelength, a second group of the first fibers 162 are coupled with light with a second wavelength different from the first wavelength. Other details of the present embodiments are similar to those illustrated above, and thereto not repeated herein.

Reference is made to FIG. 8C. In the present embodiments, a strength rod 168 may be located at a center axis 160C of the coaxial fiber structure 160, and the first and second fibers 162 and 164 may be disposed in a ring around the strength rod 168. The filling material 166 may fill the space among the first fiber 162, the second fibers 164, the strength rod 168, and the outer jacket 165. In the present embodiments, the first and second fibers 162 and 164 and the strength rod 168 may have a same diameter. In some other embodiments, two or three of the first and second fibers 162 and 164 and strength rod 168 may have different diameters.

Reference is made to FIG. 8D. Embodiments of the present embodiments is similar to that of FIG. 8A, except that the second fibers 164 include fibers 164A and 164B, in which a diameter of the fiber 164A is greater than a diameter of the fiber 164B. The fibers 164A and 164B may have diameters greater than, substantially equal to, or less than a diameter of the first fibers 162. For example, in the present embodiments, a diameter of the fibers 164A may be substantially equal to a diameter of the first fibers 162, and a diameter of the fibers 164B may be less than a diameter of the first fibers 162. The configurations of the first fibers 162 and the second fibers 164 may be exchanged in some alternative embodiments. Other details of the present embodiments are similar to those illustrated above, and thereto not repeated herein.

Reference is made to FIG. 8E. Embodiments of the present embodiments is similar to that of FIG. 8A, except that the second fibers 164 include fibers 164A, 164B, 164C, in which a diameter of the fiber 164A is greater than a diameter of the fiber 164B, and the diameter of the fiber 164B is greater than a diameter of the fiber 164C. The fibers 164A, 164B, 164C may have diameters greater than, substantially equal to, or less than a diameter of the first fibers 162. For example, in the present embodiments, a diameter of the fibers 164A may be substantially equal to a diameter of the first fibers 162, a diameter of the fibers 164B may be less than a diameter of the fibers 162A, and a diameter of the fibers 164C may be less than a diameter of the first fibers 162. The configurations of the first fibers 162 and the second fibers 164 may be exchanged in some alternative embodiments. Other details of the present embodiments are similar to those illustrated above, and thereto not repeated herein.

Reference is made to FIG. 8F. Embodiments of the present embodiments is similar to that of FIG. 8E, except that the fiber structure 160 is an elliptical fiber. For example, the fiber structure 160 may have a short axis and a long axis greater than the short axis. In some embodiments, the fiber structure 160 in FIGS. 8A-8E may also adopt the configuration of the elliptical fiber. Other details of the present embodiments are similar to those illustrated above, and thereto not repeated herein.

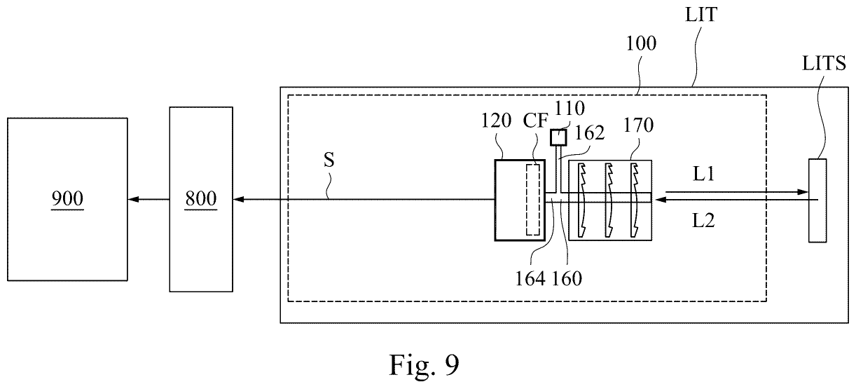

FIG. 9 is schematic view of an inspection device 100 inspecting a target component LITS in a lithography apparatus according to some embodiments of the present disclosure. Details of the present embodiments are similar to those illustrated in the embodiments of FIG. 7, except that the inspection device 100 includes a lens module 170 in addition to the light source 110, the light detector 120, and the fiber structure 160. In some embodiments, the lens module 170 may include plural Fresnel lenses. The lens module 170 may be used to focus light L1 onto the target component LITS, and guide the light L2 to the light detector 120. In some embodiments (e.g., embodiments illustrated in FIG. 3), the configuration of the lens module 170 is beneficial for capturing an image of the target component LITS. Other details of the present embodiments are similar to those illustrated above, and thereto not repeated herein.

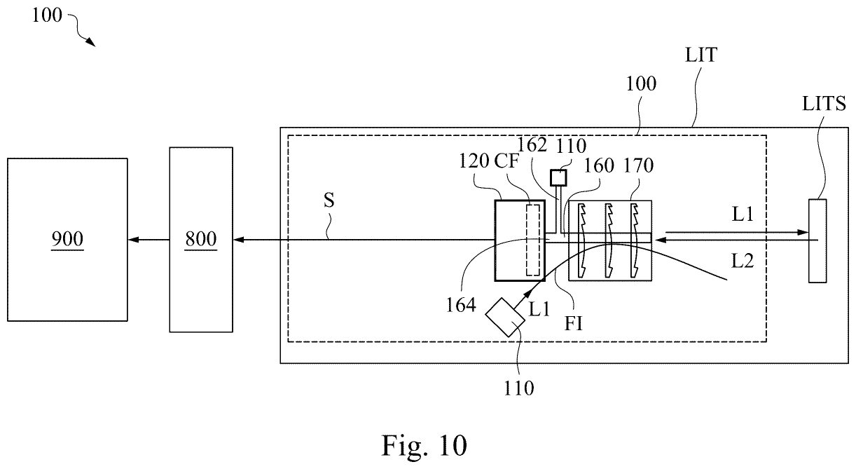

FIG. 10 is schematic view of an inspection device 100 inspecting a target component LITS in a lithography apparatus according to some embodiments of the present disclosure. Details of the present embodiments are similar to those illustrated in the embodiments of FIG. 9, except that the light source 110 is offset from a light path between the light detector 120 and the fiber structure 160, and the light source 110 is optically coupled with the fiber structure 160, for example, with a fiber FI, for providing the light L1 to the fiber structure 160. In the present embodiments, the fiber FI has a segment adjacent to the fiber structure 160 for coupling the light L1 into the fiber structure 160.

In the present embodiments, the light source 110 may be high-power light source providing the light L1 for excite the material/particles on the target component LITS. The band (color) filter CF is chosen to allow the characteristic peak of the elements (e.g., tin particles, silver nanoparticles, copper ions, CO₂, the like, or the combination thereof) to pass itself, and block light with a certain wavelength far away from the characteristic peak of the elements (e.g., tin particles, silver nanoparticles, copper ions, CO₂, the like, or the combination thereof). Other details of the present embodiments are similar to those illustrated above, and thereto not repeated herein.

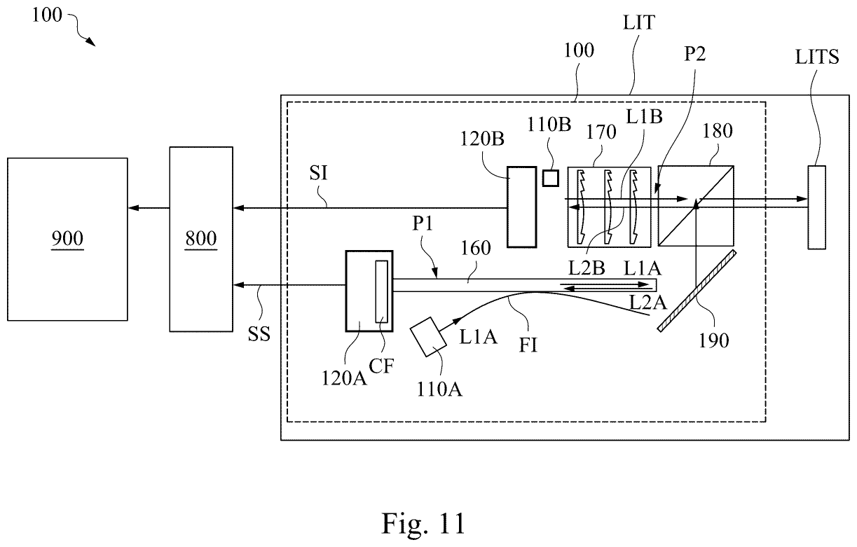

FIG. 11 is schematic view of an inspection device 100 inspecting a target LITS in a lithography apparatus according to some embodiments of the present disclosure. Details of the present embodiments are similar to those illustrated in the embodiments of FIG. 9, except that the inspection device 100 uses two inspection light paths P1 and P2 to inspect the target component LITS.

For the inspection light path P1, the inspection device 100 includes the light source 110A, the light detector 120A, the fiber structure 160, and the fiber FI. The light source 110A may be offset from the inspection light path P1 between the light detector 120A and the fiber structure 160, and the light source 110A is optically coupled with the fiber structure 160, for example, with a fiber FI, for providing the light L1 to the fiber structure 160. The light source 110A may be high-power light source providing the light L1 for excite the material/particles on the target component LITS. In some embodiments, the band (color) filter CF is chosen to allow the characteristic peak of the elements (e.g., tin particles, silver nanoparticles, copper ions, CO₂, the like, or the combination thereof) to pass itself, and block light with a certain wavelength far away from the characteristic peak of the elements (e.g., tin particles, silver nanoparticles, copper ions, CO₂, the like, or the combination thereof). And, the inspection device 100 may send the digital spectrum signal SS by the inspection light path P1.

For the inspection light path P2, the inspection device 100 includes the light source 110B, the light detector 120B, and the lens module 170. The lens module 170 may be used to focus light L1 onto the target component LITS, and guide the light L2 to the light detector 120. In some embodiments (e.g., embodiments illustrated in FIG. 3), the configuration of the lens module 170 is beneficial for capturing an image of the target component LITS. And, the inspection device 100 may send the digital image signals SI by the inspection light path P2.

In some embodiments, the inspection light path P1 is offset from the inspection light path P2. The inspection device 100 may further include a beam combiner/splitter 180 and a mirror 190 for coupling the inspection light paths P1 and P2. The beam combiner/splitter 180 may facilitate the coaxial alignment. Other details of the present embodiments are similar to those illustrated above, and thereto not repeated herein.

In some embodiments, the inspection device 100 in FIGS. 7, 9, 10, and 11 may be disposed in the scanner 200 and surrounded by the wall 290 (referring to FIG. 4), and spaced apart from the mask region 210, the substrate stage region 220, the illuminator optical module 230, the projection optical module 240 (referring to FIG. 4). In some embodiments, the inspection device 100 in FIGS. 7, 9, 10, and 11 may be disposed in the radiation source 300 and surrounded by the cover 310C (referring to FIG. 5). For example, the inspection device 100 in FIGS. 7, 9, 10, and 11 may be disposed in the lower vessel 312 or the upper vessel 314 (referring to FIG. 5). In some embodiments, the inspection device 100 in FIGS. 7, 9, 10, and 11 may be disposed between the IF-cap module 330 of the radiation source 300 and the scanner 200. In some embodiments, the inspection device 100 in FIGS. 7, 9, 10, and 11 may be disposed in the laser generator 400, and spaced apart from the main pulse seed laser source 410 and the amplifier chambers 422-428.

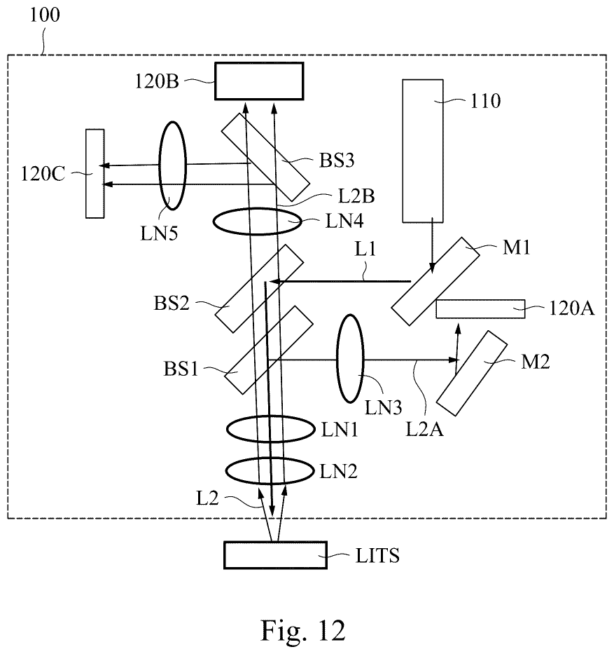

FIG. 12 is schematic view of an inspection device 100 inspecting a target component LITS in a lithography apparatus according to some embodiments of the present disclosure. Details of the present embodiments are similar to those illustrated in the embodiments of FIG. 7, except that the fiber structure 160 is omitted. In the present embodiments, the inspection device 100 includes a light source 110, light detectors 120A, 120B, and 120C. The inspection device 100 may further includes various optic elements (e.g., mirrors M1 and M2, beam splitters BS1-BS3, and lenses LN1-LN5) for directing the light L1 from the light source 110 to the target component LITS and directing the light L1 from the target component LITS to the light detectors 120A, 120B, and 120C. As aforementioned, the light detector 120A may be a spectrometer detecting a spectrum of a radiation (e.g., the light L2A), and the light detector 120B may be an image sensor. In some embodiments, the light detector 120C may detect a light intensity. In some embodiments, the lens LN2 may be an objective lens configured to focus the light L1 onto a surface of the target component LITS.

In some embodiments, the inspection device 100 in FIG. 12 may be disposed in the scanner 200 and surrounded by the wall 290 (referring to FIG. 4), and spaced apart from the mask region 210, the substrate stage region 220, the illuminator optical module 230, the projection optical module 240 (referring to FIG. 4). In some embodiments, the inspection device 100 in FIG. 12 may be disposed in the radiation source 300 and surrounded by the cover 310C (referring to FIG. 5). For example, the inspection device 100 in FIG. 12 may be disposed in the lower vessel 312 or the upper vessel 314 (referring to FIG. 5). Other details of the present embodiments are similar to those illustrated above, and thereto not repeated herein.

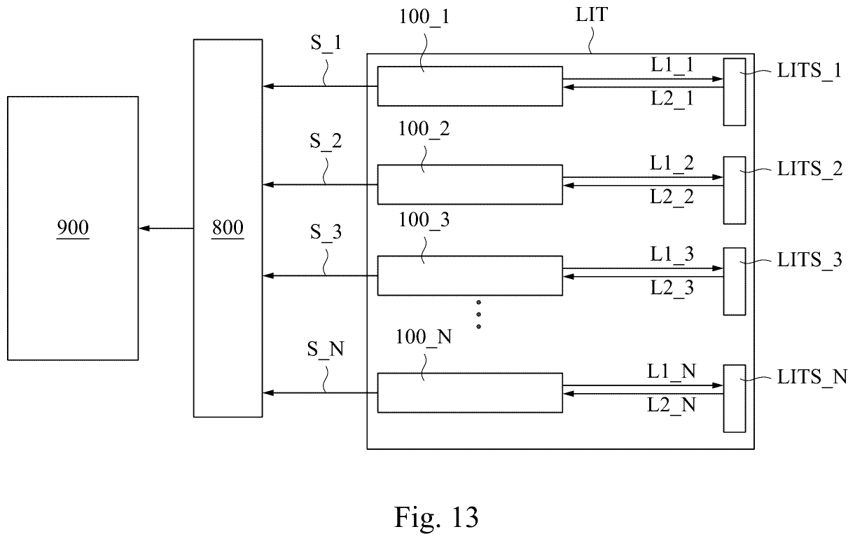

FIG. 13 is schematic view of an inspection device 100 inspecting plural target components LITS_1, LITS_2, LITS_3, and LITS_N in a lithography apparatus LIT (referring to FIG. 1) according to some embodiments of the present disclosure. The inspection device 100 may include plural inspection devices 100_1, 100_2, 100_3, and 100_N respectively inspecting the target components LITS_1, LIT_2, LIT_3, and LITS_N. For example, the inspection devices 100_1 provide light L1_1 to the target component LITS_1 and receive light L2_1 from the target component LITS_1. The inspection devices 100_2 provide light L1_2 to the target component LITS_2 and receive light L2_2 from the target component LITS_2. The inspection devices 100_3 provide light L1_3 to the target component LITS_3 and receive light L2_3 from the target component LITS_3. The inspection devices 100_N provide light L1_N to the target LITS_N and receive light L2_N from the target component LITS_N. Through the configuration, the inspection devices 100_1, 100_2, 100_3, and 100_N may send the signals S_1, S_2, S_3, S_4 to the signal convertor 800 and the controller 900.

In the present embodiments, the inspection devices 100_1, 100_2, 100_3, and 100_N may adopt any suitable configuration of the inspection device 100 illustrated in FIGS. 7, 9, 10, 11, and 12. And, the target components LITS_1, LITS_2, LITS_3, and LITS_N may be the target components illustrated in FIGS. 4-6, in which the target components LITS_1, LITS_2, LITS_3, and LITS_N are different components in the lithography apparatus LIT. In some embodiments, one or more of the light L1_1, L1_2, L1_3, L1_4 may adopt any suitable configuration of the light L1A illustrated in FIG. 2, and one or more of the light L2_1, L2_2, L2_3, L2_4 may adopt any suitable configuration of the light L2A illustrated in FIG. 2. In some embodiments, one or more of the light L1_1, L1_2, L1_3, L1_4 may adopt any suitable configuration of the light L1B illustrated in FIG. 3, and one or more of the light L2_1, L2_2, L2_3, L2_4 may adopt any suitable configuration of the light L2B illustrated in FIG. 3. The signals S_1, S_2, S_3, S_4 may be the signal S (e.g., the digital spectrum signal SS in FIG. 2 or the digital image signals SI in FIG. 3) mentioned in FIGS. 7, 9, 10, 11, and 12. Other details of the present embodiments are similar to those illustrated above, and thereto not repeated herein.

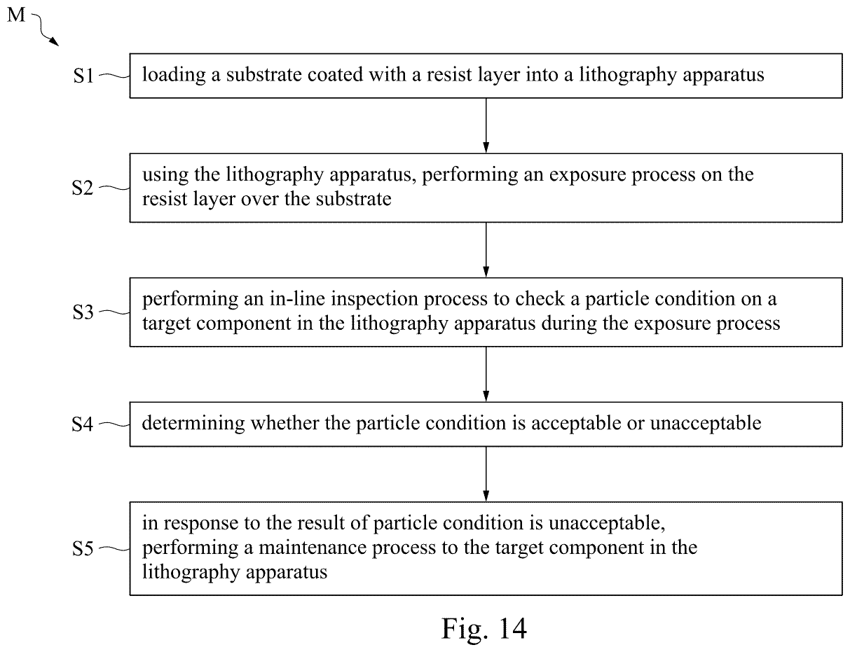

FIG. 14 is a flow chart of a method for operating a lithography apparatus according to some embodiments of the present disclosure. The method M includes steps S1-S5. It is understood that additional steps may be provided before, during, and after the steps shown in FIG. 14, and some of the steps S1-S5 described can be replaced or eliminated for additional embodiments of the method. The order of the operations/processes may be interchangeable.

At step S1, a substrate W (referring to FIG. 1) coated with a resist layer is loaded into a lithography apparatus LIT. At step S2, an exposure process is performed on the resist layer over the substrate W using the lithography apparatus LIT (referring to FIG. 1).

At step S3, an in-line inspection process is performed to check a particle condition on a target component LITS in the lithography apparatus LIT (referring to FIGS. 2 and 3) during the exposure process. The in-line inspection process may yield a result of the emission spectrum and/or the image from the target component LITS. And, a particle condition on the target component LITS can be inferred and checked from the result of the in-line inspection process.

At step S4, a determination is made whether the particle condition is acceptable or unacceptable. In some embodiments where the result of the in-line inspection process is the emission spectrum, a wavelength of characteristic peaks of the material/particles would reveal the species of the material/particles on the target component LITS, and intensity of the characteristic peaks of the material/particles would reveal the concentration/amount of the material/particles on the target component LITS. And, when the wavelength and/or the intensity of the characteristic peaks of the material/particles is within an acceptable range, the particle condition is considered as acceptable, in which the material/particles may not be too thick, and a performance of the target component LITS (e.g., a reflectivity of mirrors) can be maintained. On the other hand, when the wavelength and/or the intensity of the characteristic peaks of the material/particles is out of an acceptable range, the particle condition is considered as unacceptable, in which the material/particles may be too thick, and a performance of the target component LITS (e.g., a reflectivity of mirrors) may degrade.

In some embodiments where the result of the in-line inspection process is the images, the size, shape, and distribution of the material/particles on the target component LITS and contrast ratios of the images can be derived from the images. And, when the size, shape, and distribution of the material/particles is acceptable (e.g., the size and/or a uniformity of the particle is within an acceptable range) or the contrast ratios of the images is acceptable (e.g., a distribution uniformity of the contrast ratios is within an acceptable range), the particle condition is considered as acceptable, in which a performance of the target component LITS (e.g., a reflectivity of mirrors) can be maintained. On the other hand, when the size, shape, and distribution of the material/particles is unacceptable (e.g., the size and/or a distribution uniformity of the particle is out of the acceptable range) or the contrast ratios of the images is acceptable (e.g., a distribution uniformity of the contrast ratios is out of the acceptable range), the particle condition is considered as unacceptable, in which a performance of the target component LITS (e.g., a reflectivity of mirrors) may degrade.

At step S5, in response to the result of the particle condition is considered as unacceptable, performing a maintenance process to the target component LITS in the lithography apparatus LIT (referring to FIGS. 2 and 3). In some embodiments, the maintenance process may include cleaning a surface of the target component LITS in the lithography apparatus LIT (referring to FIGS. 2 and 3), for example, by vacuum tubes.

In some cleaning examples, referring to FIG. 14 and FIG. 4, when the target LITS are the wall 290, the mask region 210, the substrate stage region 220, the illuminator optical module 230, and the projection optical module 240 in the scanner 200, the cleaning process may be performed to clean the inner surface 290S of the wall 290, the front surface 214F of the mask 214 facing the substrate stage (or wafer stage) 222, the back surface 214B of the mask 214 facing away from the substrate stage (or wafer stage) 222, the reflective surface 215S of the plane deflection mirror 215, any surface of the optical element 216, any surface of the light shielding element 217, and any surface of the other optical elements 218.

In some cleaning examples, referring to FIG. 14 and FIG. 5, when the target component LITS are the cover 310C, the lower vessel 312, the upper vessel 314, the collector 320, the IF-cap module 330, and the gas exhaust system 340 in the radiation source 300, the cleaning process may be performed to clean the inner surface 310CS of the cover 310C, any surface of the lower vessel 312, any surface of the upper vessel 314, the reflective surface of the collector 320, any surface of the IF-cap module 330, and any surface of the gas exhaust system 340.

In some cleaning examples, referring to FIG. 14 and FIG. 6, when the target component LITS are mirrors MA, the amplifier chambers 422-428, and the quartz tubes QT in the laser generator 400, the cleaning process may be performed to clean the reflective surface of the mirrors MA, inner surfaces of the amplifier chambers 422-428, the outer surface of the quartz tubes QT, or the inner surface of the quartz tubes QT.

In some embodiments, the maintenance process may include swapping the target component LITS in the lithography apparatus LIT (referring to FIGS. 2 and 3) with a fresh component. The swapping process may include remove the target component LITS away from a location in the lithography apparatus LIT (referring to FIGS. 2 and 3) and mount/arrange a fresh component having a same performance/function as the target component LITS onto the location in the lithography apparatus LIT.

In some swapping examples, referring to FIG. 14 and FIG. 4, when the target component LITS are the mask 214, the plane deflection mirror 215, the optical element 216, the light shielding element 217, and the other optical elements 218 in the scanner 200, the swapping process may be performed to swap the mask 214, the plane deflection mirror 215, the optical element 216, the light shielding element 217, and the other optical elements 218 with fresh ones.

In some swapping examples, referring to FIG. 14 and FIG. 5, when the target component LITS are the collector 320, the IF-cap module 330, and the gas exhaust system 340 in the radiation source 300, the cleaning process may be performed to swap the collector 320, the IF-cap module 330, and the gas exhaust system 340 with fresh ones.

In some swapping examples, referring to FIG. 14 and FIG. 6, when the target component LITS are mirrors MA, the amplifier chambers 422-428, and the quartz tubes QT in the laser generator 400, the cleaning process may be performed to swap the mirrors MA, the amplifier chambers 422-428, and the quartz tubes QT with fresh ones.

Based on the above discussions, it can be seen that the present disclosure offers advantages. It is understood, however, that other embodiments may offer additional advantages, and not all advantages are necessarily disclosed herein, and that no particular advantage is required for all embodiments. An inspection device is used to in-line and real-time fast judge Sn particle/Sn Debris, metal elements, and non-metal elements (e.g., oxide elements) in a EUV lithography apparatus. An accumulated value of the Sn particle/Sn Debris, metal elements, and non-metal elements (e.g., oxide elements) can be measured by detecting an emission spectrum produced by exciting a target material and checking characteristic peaks of Sn particle/Sn Debris, metal elements, and non-metal elements (e.g., oxide elements) particle in the emission spectrum. A contamination map/image can be constructed by an imaging inspection device, in which the contamination map/image can be used for identifying Sn, its check, and its behavior/pattern. A determination is made regarding whether a component in the EUV lithography apparatus is contaminated based on the accumulated value of the Sn particle/Sn Debris, metal elements, and non-metal elements (e.g., oxide elements) identified from the contamination map/image. This determination may lead to the decision to replace the contaminated component. Microns and sub-microns Sn particle can be inspected. The imaging inspection device may use two polarized light for identify the Sn particle/Sn Debris, metal elements, and non-metal elements (e.g., oxide elements).

According to some embodiments of the present disclosure, a method includes using a laser generator, emitting a laser beam; using a radiation source, producing extreme ultraviolet (EUV) radiation by hitting the target droplet by the laser beam; using a scanner, directing the EUV radiation onto a substrate through a mask; and using a fiber structure, performing an in-line inspection process to check a particle condition in the laser generator, the radiation source, and the scanner when producing the EUV radiation.

According to some embodiments of the present disclosure, a method includes using a lithography apparatus, performing an exposure process on a resist layer over a substrate; using a fiber structure, performing an in-line inspection process to check a particle condition on a target component in the lithography apparatus during the exposure process; determining whether a result of the in-line inspection process is in an acceptable range; and in response to the result of the in-line inspection process is out of the acceptable range, performing a maintenance process to the target component in the lithography apparatus.

According to some embodiments of the present disclosure, a lithography apparatus includes a radiation source, a laser generator, a scanner, and an inspection device. The laser generator is configured to emit a laser onto a target material in a vessel of the radiation source to produce extreme ultraviolet (EUV) radiation. The scanner is configured to direct the EUV radiation onto a substrate through a mask. The inspection device is configured to inspect a target component in the radiation source, the scanner, or the laser generator. The inspection device comprises a light source configured to provide a first light to the target component, a light detector configured to receive a second light from the target component, and a fiber structure configured to guide the first light from the light source to the target component, and guide the second light from the light source to the light detector.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
using a laser generator, emitting a laser beam;
using a radiation source, producing extreme ultraviolet (EUV) radiation by hitting a target droplet by the laser beam;
using a scanner, directing the EUV radiation onto a substrate through a mask; and
using a fiber structure, performing an in-line inspection process to check a particle condition in the laser generator, the radiation source, and the scanner when producing the EUV radiation.

2. The method of claim 1, wherein performing the in-line inspection process comprises:
directing an excitation light onto a target component in one of the laser generator, the radiation source, and the scanner when producing the EUV radiation; and
detecting an emission spectrum from the target component.

3. The method of claim 1, wherein performing the in-line inspection process comprises:
directing an illuminating light onto a target component in one of the laser generator, the radiation source, and the scanner when producing the EUV radiation; and
detecting a first image from the target component.

4. The method of claim 3, wherein performing the in-line inspection process further comprises:
detecting a second image from a target component in one of the laser generator, the radiation source, and the scanner when producing the EUV radiation, wherein the first and second images are detected by different polarized light.

5. The method of claim 1, wherein the particle condition is a condition of a metal element.

6. The method of claim 1, wherein the particle condition is a condition of a non-metal element.

7. The method of claim 1, wherein the fiber structure comprises:
a first fiber configured to direct a first light onto a target component in one of the laser generator, the radiation source, and the scanner when producing the EUV radiation; and
a second fiber configured to direct a second light from the target component to a light detector.

8. The method of claim 7, wherein the target component is a mirror in the scanner.

9. A method, comprising:
using a lithography apparatus, performing an exposure process on a resist layer over a substrate;
using a fiber structure, performing an in-line inspection process to check a particle condition on a target component in the lithography apparatus during the exposure process;
determining whether a result of the particle condition is unacceptable; and
in response to the result of the particle condition is unacceptable, performing a maintenance process to the target component in the lithography apparatus.

10. The method of claim 9, wherein the maintenance process comprises:
cleaning a surface of the target component in the lithography apparatus.

11. The method of claim 9, wherein the maintenance process comprises:
swapping the target component in the lithography apparatus with a fresh component.

12. The method of claim 9, wherein the in-line inspection process is performed by directing a light onto the target component through the fiber structure.

13. The method of claim 9, wherein the in-line inspection process is performed by direct a light from the target component to a light detector through the fiber structure.

14. A lithography apparatus, comprising:
a radiation source;
a laser generator configured to emit a laser beam onto a target material in a vessel of the radiation source to produce extreme ultraviolet (EUV) radiation;
a scanner configured to direct the EUV radiation onto a substrate through a mask; and
an inspection device configured to inspect a target component in the radiation source, the scanner, or the laser generator, wherein the inspection device comprises a light source configured to provide a first light to the target component, a light detector configured to receive a second light from the target component, and a fiber structure configured to guide the first light from the light source to the target component, and guide the second light from the light source to the light detector.

15. The lithography apparatus of claim 14, wherein the light detector is a spectrometer.

16. The lithography apparatus of claim 14, wherein the light detector is an image sensor.

17. The lithography apparatus of claim 14, wherein the target component is a mirror in the radiation source.

18. The lithography apparatus of claim 14, wherein the target component is a light shielding element in the scanner, and the light shielding element block a portion of the EUV radiation from being directed to the mask in the scanner.

19. The lithography apparatus of claim 14, wherein the target component is a mirror in the scanner.

20. The lithography apparatus of claim 14, wherein a portion of a path of the first light is substantially normal to a surface of the target component, and a path of the second light is substantially normal to the surface of the target component.
